(19) United States
(12) Patent Application Publication
(10) Pub. No.: US 2026/0255470 A1
(43) Pub. Date: Aug. 27, 2026

(54) HIGH-FREQUENCY SUBSTRATE

(71) Applicant: SUMITOMO ELECTRIC PRINTED CIRCUITS, INC., Shiga (JP)

(72) Inventors: Kosuke AKIRA, Shiga (JP); Ayaka IZUMI, Shiga (JP); Akihiro YANO, Shiga (JP); Katsuya MORIZANE, Shiga (JP); Yukinori NISHIMURA, Shiga (JP)

(73) Assignee: SUMITOMO ELECTRIC PRINTED CIRCUITS, INC., Shiga (JP)

(21) Appl. No.: 19/163,091

(22) PCT Filed: Feb. 21, 2024
(86) PCT No.: PCT/JP2024/006143

§ 371 Date: Sep. 8, 2025

(30) Foreign Application Priority Data
Mar. 9, 2023 (JP) 2023-036979

(51) Int. Cl. H05K 1/02; H05K 1/03; H05K 1/11

(52) U.S. Cl. CPC H05K 1/024; H05K 1/036; H05K 1/113

(57) ABSTRACT

A high-frequency substrate according to the present disclosure includes: a first layered body in which a first electrically conductive layer and a first resin layer are layered; a second layered body in which a second electrically conductive layer and a second resin layer are layered, said second layered body being disposed so as to face the first layered body; a first via hole; and a second via hole, the first layered body having an electrically conductive pattern, the electrically conductive pattern having a signal line and a ground layer, a bottom surface of the first via hole being in contact with the ground layer.

### TECHNICAL FIELD

The present disclosure relates to a high-frequency substrate. This application claims priority based on Japanese Patent Application No. 2023-036979 filed on Mar. 9, 2023, the entire contents of which are incorporated herein by reference.

### BACKGROUND ART

A high-frequency substrate is used to transmit a high-frequency signal, a digital signal, or the like. As such a high-frequency substrate, a high-frequency substrate with a shielding function having a strip line structure, a microstrip structure, or the like is used for noise prevention, crosstalk prevention, or the like. The strip line structure and the microstrip structure are structures in which a signal line is disposed on one surface of a dielectric layer.

In a printed wiring board (substrate) configured to transmit an electrical signal, when the frequency of the electrical signal to be transmitted becomes high, the dielectric loss due to an insulating material around a conductor becomes large. Thus, it has been proposed to use fluororesin having a small dielectric constant and a small dielectric loss tangent as an insulating material around a conductor in a printed wiring board (see Patent literature 1).

### CITATION LIST

### Patent Literature

Patent literature 1: Japanese Unexamined Patent Application Publication No. 2013-165171

### Summary of Invention

A high-frequency substrate according to one aspect of the present disclosure includes a first layered body in which a first electrically conductive layer and a first resin layer are stacked, a second layered body in which a second electrically conductive layer and a second resin layer are stacked, the second layered body being disposed so as to face the first layered body, an adhesive layer bonding the first resin layer and the second resin layer to each other, a first via hole formed at an inner periphery and a bottom of one or a plurality of connection holes penetrating the first resin layer in a thickness direction, and a second via hole formed at an inner periphery and a bottom of one or a plurality of connection holes penetrating the second resin layer and the adhesive layer in the thickness direction. The first layered body has an electrically conductive pattern stacked on a surface of the first resin layer facing the second layered body. The electrically conductive pattern is embedded in the adhesive layer. The electrically conductive pattern has a signal line, and ground lines disposed on both sides of the signal line. A bottom surface of the first via hole is in contact with the ground layer, and the first via hole electrically connects the first electrically conductive layer and the ground layer to each other. A bottom surface of the second via hole is in contact with the ground layer, and the second via hole electrically connects the second electrically conductive layer and the ground layer to each other. The first resin layer and the second resin layer are mainly composed of a resin having a coefficient of linear expansion of 20 ppm/K or more from 20° C. to 120° C. The first electrically conductive layer has a first opening portion in a peripheral region of an opening of the first via hole. The second electrically conductive layer has a second opening portion in a peripheral region of an opening of the second via hole.

### BRIEF DESCRIPTION OF THE DRAWINGS

FIG. 1 is a schematic partial perspective view showing a high-frequency substrate according to an embodiment of the present disclosure.

FIG. 2 is a schematic partial plan view showing a high-frequency substrate according to an embodiment of the present disclosure.

FIG. 3 is a cross-sectional view taken along a line III-III of FIG. 2.

FIG. 4 is a cross-sectional view taken along a line IV-IV of FIG. 2.

FIG. 5 is a schematic partial plan view showing a high-frequency substrate according to an embodiment of the present disclosure.

FIG. 6 is a schematic partial plan view showing a high-frequency substrate according another embodiment of the present disclosure.

FIG. 7 is a schematic partial plan view showing a high-frequency substrate according to another embodiment of the present disclosure.

FIG. 8 is a schematic fragmentary sectional view showing a high-frequency substrate according to another embodiment of the present disclosure.

FIG. 9 is a schematic fragmentary sectional view showing a high-frequency substrate according to another embodiment of the present disclosure.

FIG. 10 is a schematic partial bottom plan view showing a high-frequency substrate according to another embodiment of the present disclosure.

FIG. 11 is a schematic fragmentary sectional view showing a high-frequency substrate according to an example 1.

FIG. 12 is a schematic fragmentary sectional view showing a high-frequency substrate according to a comparative example 1.

### DETAILED DESCRIPTION

### Problems to be Solved by Present Disclosure

In recent years, as electronic devices have been downsized, it has been desired to increase the wiring density of a substrate, and thus, a multilayer printed wiring board having a plurality of electrically conductive layers formed thereon has been used. In such a multilayer printed wiring board, a via hole (a tubular conductor) is formed to connect different electrically conductive layers. However, when a resin having excellent high-frequency characteristics but a large coefficient of linear expansion, such as fluororesin, is used, the dimensional change in the thickness direction between the electrically conductive layers becomes large under an environment where a temperature variation is large, such as a thermal shock test. Thus, since a stress is locally applied to the conductive plating of the inner wall of the via hole and a crack is generated, there is a concern that the electrical connection reliability of the high-frequency substrate may be impaired.

The present disclosure has been made under such circumstances, and an object thereof is to provide a high-frequency substrate capable of reducing stress applied to a via hole even when a resin having a large coefficient of linear expansion is used.

### Advantageous Effects of Present Disclosure

According to the present disclosure, a high-frequency substrate capable of reducing stress applied to a via hole even when a resin having a large coefficient of linear expansion is used can be provided.

### Description of Embodiments of Present Disclosure

First, embodiments of the present disclosure will be listed and described.

(1) A high-frequency substrate according to one aspect of the present disclosure includes a first layered body in which a first electrically conductive layer and a first resin layer are stacked, a second layered body in which a second electrically conductive layer and a second resin layer are stacked, the second layered body being disposed so as to face the first layered body, an adhesive layer bonding the first resin layer and the second resin layer to each other, a first via hole formed at an inner periphery and a bottom of one or a plurality of connection holes penetrating the first resin layer in a thickness direction, and a second via hole formed at an inner periphery and a bottom of one or a plurality of connection holes penetrating the second resin layer and the adhesive layer in the thickness direction. The first layered body has an electrically conductive pattern stacked on a surface of the first resin layer facing the second layered body. The electrically conductive pattern is embedded in the adhesive layer. The electrically conductive pattern has a signal line, and ground lines disposed on both sides of the signal line. A bottom surface of the first via hole is in contact with the ground layer, and the first via hole electrically connects the first electrically conductive layer and the ground layer to each other. A bottom surface of the second via hole is in contact with the ground layer, and the second via hole electrically connects the second electrically conductive layer and the ground layer to each other. The first resin layer and the second resin layer are mainly composed of a resin having a coefficient of linear expansion of 20 ppm/K or more from 20° C. to 120° C. The first electrically conductive layer has a first opening portion in a peripheral region of an opening of the first via hole. The second electrically conductive layer has a second opening portion in a peripheral region of an opening of the second via hole.

When a resin having a large coefficient of linear expansion, such as a coefficient of linear expansion of 20 ppm/K or more from 20° C. to 120° C., is adopted as the main component resin of the resin layer of the high-frequency substrate, the dimensional change in the thickness direction between the electrically conductive layers tends to be large under an environment where a temperature change between a high temperature and a low temperature occurs rapidly. Thus, since a stress is locally applied to the conductive plating of the inner wall of the via hole and a crack is generated, there is a concern that the electrical connection reliability of the high-frequency substrate may be impaired. The high-frequency substrate of the present disclosure includes the first via hole electrically connecting the first electrically conductive layer and the ground layer, and the second via hole electrically connecting the second electrically conductive layer and the ground layer. The first electrically conductive layer has the first opening portion in the peripheral region of the opening of the first via hole, and the second electrically conductive layer has the second opening portion in the peripheral region of the opening of the second via hole.

Thus, even when the high-frequency substrate is used in an environment where a temperature variation is large, such as a thermal shock test, and the resin is thermally expanded, the stress generated by the thermally expanded resin is dispersed by the first opening portion and the second opening portion. Thus, the stress locally applied to the conductive plating of the inner wall of the via hole is reduced. Thus, it is possible to suppress the occurrence of cracks in the conductive plating of the inner wall of the via hole. Thus, in the high-frequency substrate of the present disclosure, even when a resin having a large coefficient of linear expansion with respect to a temperature change is used, the stress applied to the via hole can be reduced, and the high-frequency substrate has high resistance to a thermal shock test. The electrical connection reliability of the high-frequency substrate can be enhanced.

Here, the “coefficient of linear expansion” is a linear expansion coefficient in the thickness direction measured in accordance with the method for testing dynamic mechanical properties described in JIS-K7244-4 (1999), and is a value calculated from the dimensional change of the thin sheet with respect to the temperature change with a tensile mode in thermomechanical analysis (TMA) under conditions of a temperature range of 20° C. to 120° C., a temperature increase rate of 5° C./min, a frequency of 10 Hz, and a strain of 0.05%. The main component refers to a component having the highest content among the components constituting the resin layer. As an example, the “main component” refers to a component whose content is more than 50 mass %. The “peripheral region of the opening of the first via hole” means, in a plan view, a region in which the ratio of the distance from the opening edge of the first via hole to the average diameter of the opening of the first via hole is 2 or less. Similarly, the “peripheral region of the opening of the second via hole” means, in a plan view, a region in which the ratio of the distance from the opening edge of the second via hole to the average diameter of the opening of the second via hole is 2 or less.

(2) In the above (1), at least one of the first electrically conductive layer and the second electrically conductive layer may further have third opening portions. The third opening portions may be provided at a position of the first electrically conductive layer indirectly facing the bottom surface of the second via hole and a position of the second electrically conductive layer indirectly facing the bottom surface of the first via hole. Since at least one of the first electrically conductive layer and the second electrically conductive layer further includes the third opening portion, the stress generated by the thermally expanded resin is further dispersed, and the stress locally applied to the conductive plating of the inner wall of the via hole is further reduced. Thus, it is possible to further suppress the occurrence of cracks in the conductive plating of the inner wall of the via hole. Thus, the electrical connection reliability of the high-frequency substrate can be further enhanced.

### Description of Embodiments of Present Disclosure

Hereinafter, each embodiment of high-frequency substrates according to the present disclosure will be described in detail with reference to the drawings.

### <High-Frequency Substrate>

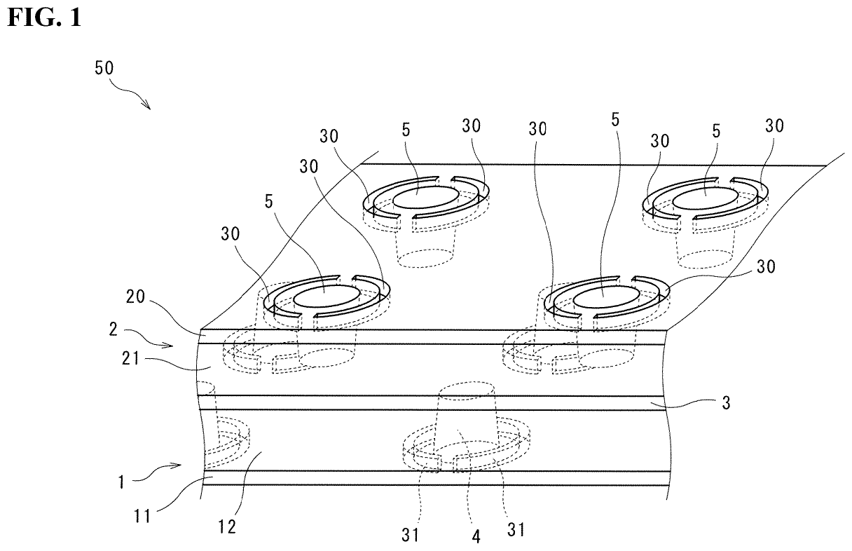

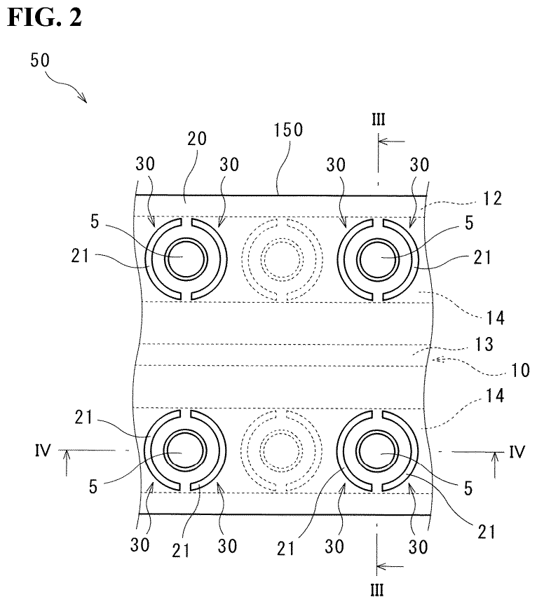

A high-frequency substrate 50 can be suitably used as a wiring body for high-frequency transmission. Reference is made to FIGS. 1 and 2. The high-frequency substrate 50 includes a first layered body 1, an adhesive layer 3, a second layered body 2 disposed to face the first layered body 1 with the adhesive layer 3 interposed between the first layered body 1 and the second layered body 2, one or more first via holes 4, and one or more second via holes 5. The via holes in the present disclosure may be blind via holes.

The lower limit of the average thickness of the high-frequency substrate 50 may be 110 μm, 120 μm, or 130 μm. The upper limit of the average thickness of the high-frequency substrate 50 may be 450 μm, 440 μm, or 430 μm. When the average thickness of the high-frequency substrate 50 is within the above range, a sufficient transmission bandwidth and desired flexibility can be obtained.

### First Layered Body

The first layered body 1 includes a first resin layer 12, a first electrically conductive layer 11, and an electrically conductive pattern 10. In the first layered body 1, the first electrically conductive layer 11 and the first resin layer 12 are stacked. The electrically conductive pattern 10 is stacked on a surface of the first resin layer 12 facing the second layered body 2.

### (First Resin Layer)

The first resin layer 12 is a resin layer on which the electrically conductive pattern 10 is stacked. The first resin layer 12 contains a resin having a coefficient of linear expansion of 20 ppm/K or more from 20° C. to 120° C. as a main component. The high-frequency substrate 50 has excellent high-frequency characteristics by using, as a main component, a resin having a coefficient of linear expansion of 20 ppm/K or more from 20° C. to 120° C. in the first resin layer 12. When the coefficient of linear expansion of the main component resin of the first resin layer 12 from 20° C. to 120° C. is 20 ppm/K or more, the dimensional change in the thickness direction between the electrically conductive layers tends to be large under an environment where the temperature variation is large, such as a thermal impact test. Thus, since a stress is likely to be locally applied to the conductive plating of the inner wall of the via hole, the advantageous effect of the present disclosure is exhibited. The upper limit of the coefficient of linear expansion from 20° C. to 120° C. in the main component resin of the first resin layer 12 may be 500 ppm/K. When the coefficient of linear expansion of the main component resin of the first resin layer 12 is 500 ppm/K or less, the electrical connection reliability is good.

### (Main Component Resin of First Resin Layer)

Specific examples of the main component resin of the first resin layer 12 include fluororesin. Examples of the fluororesin include tetrafluoroethylene/hexafluoropropylene copolymer (FEP), tetrafluoroethylene/perfluoroalkyl vinyl ether copolymer (PFA), polytetrafluoroethylene (PTFE), and tetrafluoroethylene/perfluorodioxole copolymer (TFE/PDD).

The main component resin of the first resin layer 12 may be FEP and PTFE. In the high-frequency substrate 50, the electrically conductive pattern 10 (a signal line 13 and a ground layer 14) is disposed between the first resin layer 12 and a second resin layer 21. Fluororesin generally tends to have a low dielectric loss tangent (tan 8) and a low relative dielectric constant (Er). By using fluororesin as a main component for the first resin layer 12 and the second resin layer 21, the transmission loss of the electrically conductive pattern 10 (particularly, the signal line 13) can be sufficiently reduced, and a sufficient transmission speed can be obtained. Thus, it is not necessary to thicken the first resin layer 12 and the second resin layer 21 in order to improve the transmission characteristics. The first resin layer 12 and the second resin layer 21 can be made thin.

A sheet-like reinforcing material may be disposed inside the first resin layer 12. By disposing the sheet-like reinforcing material in the first resin layer 12, the linear expansion is suppressed in both the thickness direction and the plane direction. Thus, the dimensional stability can be improved, and the temperature dependence of the electrical characteristics represented by the relative dielectric constant can be reduced.

As the sheet-like reinforcing material, for example, a film, a woven fabric, or a nonwoven fabric (hereinafter, the nonwoven fabric and the woven fabric are also collectively referred to as “cloth”) can be used. Among these materials, woven fabrics and nonwoven fabrics may be used. By using a woven fabric or a nonwoven fabric as the sheet-like reinforcing material, an impregnated structure in which the sheet-like reinforcing material is impregnated with the resin can be formed. As a result, the linear expansion of the first resin layer 12 is easily suppressed.

The main component of the material constituting the sheet-like reinforcing material may be glass and a synthetic resin from the viewpoint of the effect of improving the dimensional stability. A specific example of the main component of the material forming the sheet-like reinforcing material is a glass cloth obtained by processing a glass fiber into a cloth shape. Other examples include a fluororesin-containing glass cloth obtained by impregnating such glass cloth with fluororesin. In addition, an inorganic cloth obtained by processing an inorganic fiber such as a metal or a ceramic into a cloth shape is exemplified. Other examples include resin cloth obtained by processing synthetic resin fibers such as polytetrafluoroethylene, polyether ether ketone, aramid, and liquid crystal polymer (LCP) into a cloth shape. Other examples include heat-resistant films containing, as a main component, polytetrafluoroethylene, liquid crystal polymer, polyimide, poly amide-imide, polybenzimidazole, polyether ether ketone, polytetrafluoroethylene, tetrafluoroethylene-perfluoroalkyl vinyl ether copolymer, a thermosetting resin, a crosslinked resin, or the like.

The first resin layer 12 may contain an optional component as necessary in addition to the main component resin. Examples of the optional component of the first resin layer 12 include a flame retardant, a flame retardant aid, a pigment, an antioxidant, a reflection imparting agent, a masking agent, a lubricant, a processing stabilizer, a plasticizer, and a foaming agent.

The lower limit of the average thickness of the first resin layer 12 may be 40 μm, or may be 45 μm. When the average thickness of the first resin layer 12 is less than 40 μm, the dielectric loss tangent increases, and the transmission loss may not be sufficiently reduced, and the manufacturing operation of the high-frequency substrate 50 may become difficult. The upper limit of the average thickness of the first resin layer 12 may be 130 μm, or may be 125 μm. When the average thickness of the first resin layer 12 exceeds 130 μm, the thicknesses of the first resin layer 12 and the high-frequency substrate 50 become unnecessarily large, and the sufficient flexibility may not be obtained. Here, the “average thickness” refers to an average value of thicknesses measured at any 100 points. In the following, the term “average thickness” of other members and the like is also defined in the same manner.

### Electrically Conductive Pattern

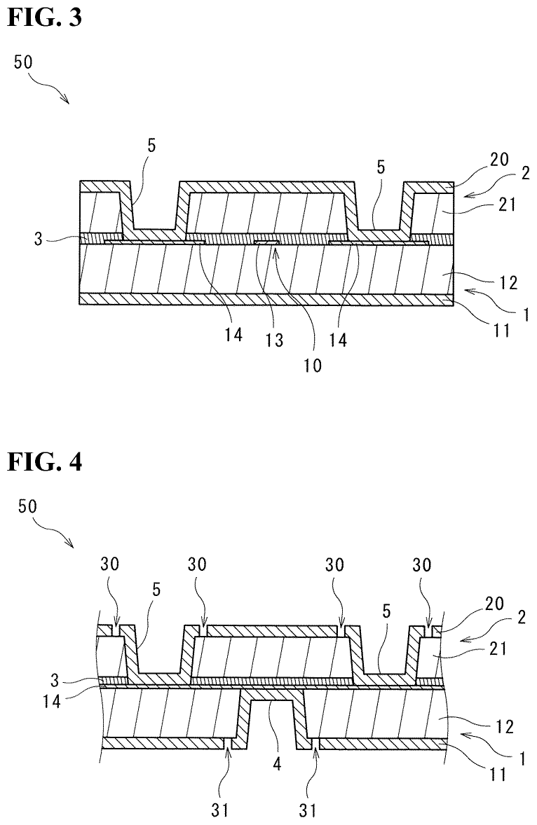

As shown in FIG. 3, the first layered body 1 has the electrically conductive pattern 10 stacked on a surface of the first resin layer 12 facing the second layered body 2. The electrically conductive pattern 10 is embedded in the adhesive layer 3. The electrically conductive pattern 10 includes the signal line 13 for a high frequency signal and the ground layer 14. In the embodiment, the electrically conductive pattern 10 includes the signal line 13 and the two ground layers 14 disposed on both sides of the signal line 13.

### (Signal Line)

As shown in FIG. 4, the signal line 13 is formed linearly on the surface of the first resin layer 12. The signal line 13 is disposed near the center of the surface of the first resin layer 12 in a direction perpendicular to the longitudinal direction of the electrically conductive pattern 10.

The lower limit of the average thickness of the signal line 13 may be 1 μm, may be 3 μm, or may be 5 μm. The upper limit of the average thickness of the signal line 13 may be 40 μm, may be 30 μm, or may be 20 μm. When the average thickness of the signal line 13 is less than 1 μm, the transmission loss in the signal line 13 may become too large. When the average thickness of the signal line 13 exceeds 40 μm, the high-frequency substrate 50 becomes unnecessarily thick, and thus there is a concern that the manufacturing cost may increase and the flexibility may decrease.

The average width of the signal line 13 is determined in accordance with the required impedance, and is not particularly limited. The lower limit of the average width of the signal line 13 may be 20 μm, may be 30 μm, or may be 40 μm. The upper limit of the average width of the signal line 13 may be 300 μm, or may be 200 μm. When the average width of the signal line 13 is less than 20 μm, the transmission loss in the signal line 13 may become too large. When the average width of the signal line 13 exceeds 500 μm, the capacitance between the signal line 13 and the ground layer 14 increases, and thus the variation in the characteristic impedance of the signal line 13 may not be sufficiently reduced.

### (Ground Layer)

The pair of ground layers 14 are disposed so as to sandwich the signal line 13 and to have a space with the signal line 13. The pair of ground layers 14 are disposed so as to extend in the longitudinal direction along a long side 150 of the first resin layer 12.

The average thickness of the ground layer 14 is not particularly limited. The lower limit of the average thickness of the ground layer 14 may be 1 μm, may be 3 μm, or may be 5 μm. The upper limit of the average thickness of the ground layer 14 may be 40 μm, may be 30 μm, or may be 20 μm. When the average thickness of the ground layer 14 is less than 1 μm, the conductivity of the ground layer 14 itself is not sufficiently obtained, and the shielding effect by the ground layer 14 may not be sufficiently obtained. When the average thickness of the ground layer 14 exceeds 40 μm, the flexibility of the high-frequency substrate 50 may be excessively reduced, and the ground layer 14 may affect the parasitic capacitance, making it difficult to obtain impedance matching.

The average width of the ground layer 14 is not particularly limited. The lower limit of the average width of the ground layer 14 may be 100 μm, or may be 200 μm. The upper limit of the average width of the ground layer 14 may be 600 μm, or may be 500 μm. When the average width of the ground layer 14 is less than 100 μm, the conductivity of the ground layer 14 itself is not sufficiently obtained, and the shielding effect by the ground layer 14 may not be sufficiently obtained. When the average width of the ground layer 14 exceeds 600 μm, the high-frequency substrate 50 may become too large in the width direction.

The average interval between the signal line 13 and the ground layer 14 in the width direction is not particularly limited. The lower limit of the average interval may be 50 μm, or may be 100 μm. The upper limit of the average interval may be 600 μm, may be 500 μm, or may be 400 μm. When the average interval is within the above range, the influence of the ground layer 14 on the parasitic capacitance can be suppressed, and the impedance matching can be improved.

The electrically conductive pattern 10 is formed by etching a metal layer stacked on one surface of the first resin layer 12, for example. The metal layer may be formed of a material having conductivity. By forming the metal layer with the copper foil, a pattern having a desired shape can be easily and reliably formed. The electrically conductive pattern 10 may be plated on the surface. The plating treatment may be tin plating, gold plating, or solder plating.

### (First Electrically Conductive Layer)

The first electrically conductive layer 11 serves as a ground layer and a shield of the signal line 13. The first electrically conductive layer 11 is stacked on a surface of the first resin layer 12 opposite to a surface facing the second layered body 2. The first electrically conductive layer 11 may be formed of a metal layer. The metal layer constituting the first electrically conductive layer 11 may be the same as the metal layer constituting the electrically conductive pattern 10.

As shown in FIG. 1, the first electrically conductive layer 11 is formed in a solid state, similarly to a second electrically conductive layer 20. Thus, the high-frequency substrate 50 has a high shielding effect of the first layered body 1. The term “solid state” means a state in which there is substantially no opening in a region overlapping at least the signal line 13 in a plan view. The phrase “substantially no opening” includes the case where openings are not completely present, and the case where minute holes such as air bubbles are present.

The lower limit of the average thickness of the first electrically conductive layer 11 may be 10 μm, or may be 20 μm. The upper limit of the average thickness of the first electrically conductive layer 11 may be 60 μm, or may be 50 μm.

### Second Layered Body

As shown in FIGS. 1 to 3, the second layered body 2 is disposed to face the first layered body 1 via the adhesive layer 3. In the second layered body 2, the second electrically conductive layer 20 and the second resin layer 21 are stacked.

(Second electrically conductive layer) The second electrically conductive layer 20 serves as a ground layer and a shield of the signal line 13. The second electrically conductive layer 20 is stacked on a surface of the second resin layer 21 opposite to a surface facing the first layered body 1.

The second electrically conductive layer 20 may be formed of a metal layer as in the case of the first electrically conductive layer 11, and the metal layer constituting the second electrically conductive layer 20 may be the same as the metal layer constituting the electrically conductive pattern 10. As shown in FIG. 1, the second electrically conductive layer 20 is formed in a solid state, similarly to the first electrically conductive layer 11.

Thus, the high-frequency substrate 50 has a high shielding effect of the second layered body 2. In addition, the high-frequency substrate 50 has the first electrically conductive layer 11 and the second electrically conductive layer 20 stacked on the outer surfaces of the first resin layer 12 and the second resin layer 21. That is, the electrically conductive pattern 10 (signal line 13) is disposed between the first electrically conductive layer 11 and the second electrically conductive layer 20. Thus, the first electrically conductive layer 11 and the second electrically conductive layer 20 can function as shields against the electrically conductive pattern 10 (signal line 13).

The lower limit of the average thickness of the second electrically conductive layer 20 may be 10 μm, or may be 20 μm. The upper limit of the average thickness of the second electrically conductive layer 20 may be 60 μm, or may be 50 μm. The lower limit of the average thickness of the second electrically conductive layer 20 may be the same as the lower limit of the average thickness of the first electrically conductive layer 11. The upper limit of the average thickness of the second electrically conductive layer 20 may be the same as the upper limit of the average thickness of the first electrically conductive layer 11.

### (Second Resin Layer)

The second resin layer 21 contains a resin having a coefficient of linear expansion of 20 ppm/K or more from 20° C. to 120° C. as a main component, and may contain optional components other than the sheet-like reinforcing member and the main component resin. The main component resin, the sheet-like reinforcing material, and the optional component of the second resin layer 21 may be the same as those of the first resin layer 12.

### Adhesive Layer

The adhesive layer 3 is disposed between the first layered body 1 and the second layered body 2. The adhesive layer 3 bonds the first resin layer 12 and the second resin layer 21.

The material constituting the adhesive layer 3 is not particularly limited as long as it is a material having insulation and adhesion. The material constituting the adhesive layer 3 may be selected from the known materials, and may be, for example, fluororesin.

The example of the fluororesin used for the adhesive layer 3 include the fluororesin exemplified as the main component resin of the first resin layer 12. By forming the adhesive layer 3 with the material containing fluororesin as a main component, the signal line 13 is embedded in the insulating material containing fluororesin as a main component. The signal line 13 is surrounded by the adhesive layer 3 and the first resin layer 12 that are insulating materials containing fluororesin as a main component, so that the transmission loss in the signal line 13 can be sufficiently reduced and a sufficient transmission speed can be obtained.

The average thickness of the adhesive layer 3 is not particularly limited as long as it is larger than the average thickness of the electrically conductive pattern 10. The lower limit of the average thickness of the adhesive layer 3 may be 10 μm, or may be 20 μm. The upper limit of the average thickness of the adhesive layer 3 may be 60 μm, or may be 50 um. When the average thickness of the adhesive layer 3 is 10 μm or more, the adhesive layer 3 is easily formed, and a good adhesion state between the first layered body 1 and the second layered body 2 can be obtained. When the average thickness of the adhesive layer 3 is 60 μm or less, the flexibility of the high-frequency substrate 50 can be favorably maintained, and an increase in dielectric loss in the adhesive layer 3 can be suppressed.

### First Via Hole

The high-frequency substrate 50 includes the first via hole 4 formed at an inner periphery and a bottom of a plurality of connection holes penetrating the first resin layer 12 in a thickness direction. That is, the plurality of first via holes 4 are provided in the first resin layer 12. In a multilayer high-frequency substrate in which the wiring density of the substrate is increased with the miniaturization of electronic devices, a via hole (a tubular conductor) connecting different electrically conductive layers is formed. As shown in FIGS. 3 and 4, the bottom surface of the first via hole 4 is in contact with the ground layer 14, and the first via hole 4 electrically connects the first electrically conductive layer 11 and the ground layer 14. The first via hole 4 penetrates the first resin layer 12 in the thickness direction on both sides of the signal line 13 and is connected to the ground layer 14.

The inner diameter of the first via hole 4 is not particularly limited. The inner diameter of the first via hole 4 may be 0.5 mm or more. The position, number, size, and the like of the first via hole 4 are not particularly limited, and can be designed as appropriate.

### Second Via Hole

The high-frequency substrate 50 includes the second via hole 5 formed at an inner periphery and a bottom of a plurality of connection holes penetrating the second resin layer 21 and the adhesive layer 3 in a thickness direction. The plurality of second via holes 5 are provided in the second resin layer 21 and the adhesive layer 3. As shown in FIGS. 3 and 4, the bottom surface of the second via hole 5 is in contact with the ground layer 14, and the second via hole 5 electrically connects the second electrically conductive layer 20 and the ground layer 14. These second via holes 5 penetrate the second resin layer 21 and the adhesive layer 3 in the thickness direction at both ends of the signal line 13 and are connected to the ground layer 14.

The inner diameter of the second via hole 5 is not particularly limited. The inner diameter of the second via hole 5 may be 0.5 mm or more. The position, number, size, and the like of the second via holes 5 are not particularly limited, and can be designed as appropriate.

### First Opening Portion and Second Opening Portion

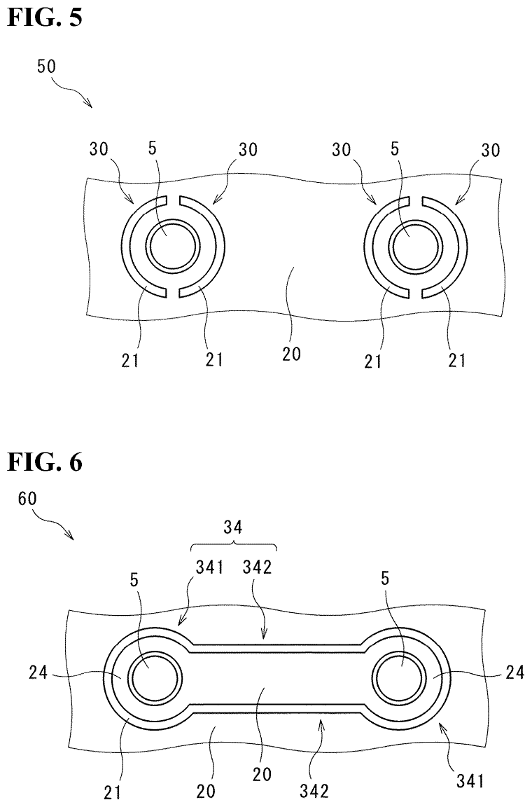

As shown in FIG. 5, in the high-frequency substrate 50, the second electrically conductive layer 20 has two second opening portions 30 in the peripheral region of the opening of the second via hole 5. The semicircular arc-shaped second opening portions 30 are provided around the opening of the second via hole 5 so as to face each other. In other words, the second electrically conductive layer 20 is not present on the upper surface of the second resin layer 21 in the region of the second opening portion 30. In addition, as shown in FIG. 1, the peripheral region of the opening of the first via hole 4 in the first electrically conductive layer 11 has two semicircular arc-shaped first opening portions 31. Since the high-frequency substrate 50 has the second opening portion 30 and the first opening portion 31, even when the high-frequency substrate 50 is used in an environment where a temperature variation is large, such as a thermal shock test and the resin having a high coefficient of linear expansion is thermally expanded, the stress generated by the thermally expanded resin is dispersed. The stress locally applied to the conductive plating of the inner wall of the first via hole 4 and the second via hole 5 is reduced. Thus, it is possible to suppress the occurrence of cracks in the conductive plating of the inner wall of the first via hole 4 and the second via hole 5.

The shapes of the first opening portion 31 and the second opening portion 30 are not particularly limited.

As shown in FIG. 6, in a high-frequency substrate 60, the second electrically conductive layer 20 has a second opening portion 34 surrounding a peripheral edge portion 24 of the opening of the two second via holes 5. Specifically, the second opening portion 34 has a flat shape having a pair of curved surface portions 341 and a pair of straight line portions 342 connecting the pair of curved surface portions 341 in a plan view. Each curved surface portion 341 surrounds a region of both sides in a direction in which the two peripheral edge portions 24 face each other in a plan view.

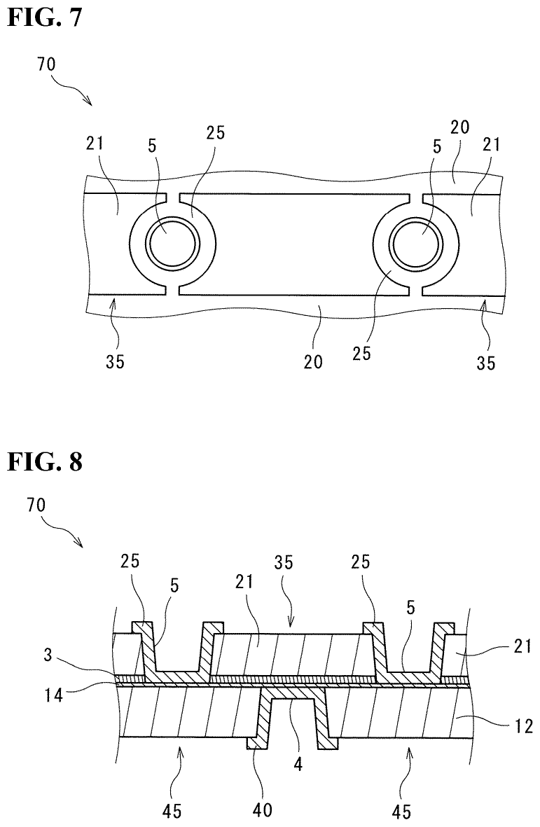

As shown in FIG. 7, in a high-frequency substrate 70, the second electrically conductive layer 20 has a second opening portion 35 in a peripheral region of the opening of the second via hole 5. The second opening portion 35 is provided in a region excluding the peripheral edge portion 25 of the opening of the second via hole 5. As shown in FIG. 8, the first electrically conductive layer 11 has a first opening portion 45 in a peripheral region of the opening of the first via hole 4. The first opening portion 45 is provided in a region excluding a peripheral edge portion 40 of the opening of the first via hole 4. Also in the high-frequency substrate 70, by having the second opening portion 35 and the first opening portion 45, when the high-frequency substrate 70 is used in an environment with a large temperature change such as a thermal shock test and the resin having a high coefficient of linear expansion thermally expands, the stress generated by the thermally expanded resin is dispersed. Stress locally applied to the conductive plating of the inner wall of the first via hole 4 and the second via hole 5 is reduced.

### Method of manufacturing high-frequency substrate The high-frequency substrate is obtained by a manufacturing method including, for example, the following five steps.

(1) Step of forming an electrically conductive pattern on one surface of a first resin layer (electrically conductive pattern forming step)
(2) Step of bonding a first layered body and a second layered body (layered body bonding step)
(3) Step of forming a first via hole (first via hole forming step)
(4) Step of forming a second via hole (second via hole forming step)
(5) Step of forming an opening portion (opening portion forming step)

### (Electrically Conductive Pattern Forming Step)

In the electrically conductive pattern forming step, first, a first resin layer is prepared. A first electrically conductive layer is stacked on one surface of the first resin layer and an electrically conductive layer for an electrically conductive pattern is stacked on the other surface of the first resin layer. Then, the electrically conductive pattern (signal line and ground layer) is formed on the surface of the first resin layer on which the electrically conductive layer is stacked. Specifically, the electrically conductive layer for the electrically conductive pattern of the first resin layer is patterned to form the electrically conductive pattern (signal line and ground layer) on one surface of the first resin layer. As the patterning, the known etching method, for example, dry etching or wet etching may be used. Wet etching is superior in productivity in terms of etching speed. The wet etching is performed by, for example, masking the electrically conductive layer in a portion to be the electrically conductive pattern and removing a desired portion (a portion not masked) of the electrically conductive layer using an etching solution. As the etching solution, for example, a sulfuric acid/hydrogen peroxide mixture (a mixed solution of sulfuric acid and hydrogen peroxide) or sodium persulfate may be used.

The patterning of the electrically conductive pattern may be performed before the electrically conductive layer is stacked on the surface of the first resin layer. The patterning before stacking can be perfomed by, for example, a method of patterning an electrically conductive layer formed on the surface of a release film and then bonding the electrically conductive layer to the surface of the first resin layer, or a method of stacking a punched electrically conductive layer on the surface of the first resin layer.

### (Layered Body Bonding Step)

In the layered body bonding step, a second layered body having a second electrically conductive layer on one surface thereof and a first layered body having an electrically conductive pattern formed on one surface thereof are bonded to each other. In the layered body bonding step, the first layered body and the second layered body are pressurized and heated in a state where an adhesive constituting the adhesive layer is interposed therebetween. Thus, the first layered body and the second layered body are bonded to each other. The adhesive is not particularly limited as long as it is a material having insulation and adhesion. The adhesive can be selected from the known materials, and fluororesin may be used as described above.

### (First Via Hole Forming Step)

In the first via hole forming step, a first via hole is formed in the first layered body 1. The first via hole may be formed by, for example, forming a through hole and then plating the inner wall of the through hole. Alternatively, the first via hole may be formed by filling a through hole with a conductor. The through hole may be formed by etching using a photomask or laser processing, for example. In the case of performing the plating treatment on the inner wall of the through hole, for example, electroless plating may be used. In the case of filling the through hole with a conductor, for example, a conductor paste may be used.

### (Second Via Hole Forming Step)

The second via hole forming step is a step of forming a second via hole in the first layered body and the adhesive layer. The second via hole forming step may be performed by the same method as the first via hole forming step, for example.

### (Opening Portion Forming Step)

In the opening portion forming step, a first opening portion is formed in the first electrically conductive layer, and a second opening portion is formed in the second electrically conductive layer. The first opening portion and the second opening portion can be formed by, for example, etching using a photomask or laser processing.

The respective constituent member of the high-frequency substrate obtained by the above manufacturing method are as described above.

According to the high-frequency substrate of the present disclosure, even when a resin having a large coefficient of linear expansion with respect to a temperature change is used, the stress applied to the via hole can be reduced.

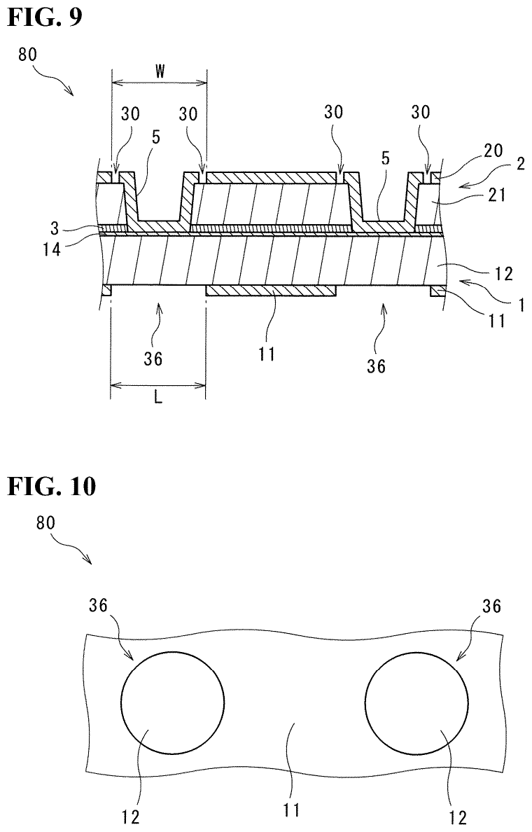

At least one of the first electrically conductive layer and the second electrically conductive layer may further include a third opening portion, and the third opening portion may be provided at a position indirectly facing a bottom surface of the second via hole in the first electrically conductive layer and a position indirectly facing a bottom surface of the first via hole in the second electrically conductive layer. Since at least one of the first electrically conductive layer and the second electrically conductive layer further has the third opening portion, the stress caused by the thermally expanded resin is further dispersed, and the stress locally applied to the conductive plating of the inner wall of the via hole is further reduced. Thus, it is possible to further suppress the occurrence of cracks in the conductive plating of the inner wall of the via hole. Thus, the electrical connection reliability of the high-frequency substrate can be further enhanced. Reference is made to FIGS. 9 and 10. The first electrically conductive layer 11 has a third opening portion 36 having a circular shape in a plan view at a position indirectly facing the bottom surface of the second via hole 5 in the first electrically conductive layer 11. Since the first electrically conductive layer 11 has the third opening portion 36 at a position indirectly facing the bottom surface of the second via hole 5 in the first electrically conductive layer 11, even when a resin having a large coefficient of linear expansion with respect to a temperature change is used, the stress applied to the second via hole 5 can be further reduced. In a high-frequency substrate 80, a hole diameter L of the third opening portion 36 is equal to a sum W of the maximum value of the inner diameters of the second via hole 5, the width of the peripheral edge portions at both ends of the second via hole 5, and the width of the second opening portion 30 adjacent to the peripheral edge portions at both ends in a cross-sectional view.

The shape of the third opening portion in a plan view may be appropriately set in accordance with the shapes of the first via hole and the second via hole. The length of the third opening portion in the longitudinal direction of the ground layer in the cross-sectional view may be set as appropriate.

The present disclosure is also directed to electronic components using the high-frequency substrate. Specifically, in the present disclosure, an electronic component in which a circuit element such as a semiconductor device or a chip resistor is electrically connected to a high-frequency substrate such as the embodiment is also within the intended scope.

The first via hole and the second via hole are not limited to the substantially cylindrical shape that increases in diameter from the lower surface toward the upper surface as in the embodiment. The via holes may have a shape in which the average diameter is non-uniform (a shape in which the diameter decreases from the lower surface toward the upper surface, or a shape having a constriction). The cross-sectional shape is not limited to a circular shape, and may be a polygonal shape or the like.

### EXAMPLES

### Example 1

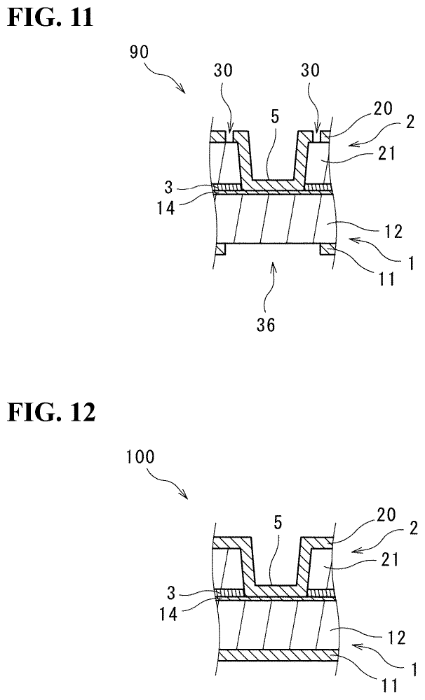

As a high-frequency substrate of an example 1, a high-frequency substrate 90 shown in FIG. 11 was produced. The high-frequency substrate 90 includes the first layered body 1, the adhesive layer 3, the second layered body 2 disposed to face the first layered body 1 with the adhesive layer 3 interposed therebetween, and the second via hole 5 having a maximum inner diameter of 250 μm. In the first layered body 1, the first electrically conductive layer 11 and the first resin layer 12 are stacked. The first layered body 1 includes the ground layer 14 that is stacked on a surface of the first resin layer 12 facing the second layered body 2. In the second layered body 2, the second electrically conductive layer 20 and the second resin layer 21 are stacked. The second electrically conductive layer 20 has two second opening portions 30 each having a width of 200 μm in the peripheral region of the opening of the second via hole 5. Further, the first electrically conductive layer 11 has the third opening portion 36 having a hole diameter of 850 μm as shown in FIG. 10 at a position indirectly facing the bottom surface of the second via hole 5 in the first electrically conductive layer 11. The materials and average thicknesses of the members included in the high-frequency substrate 90 are as follows.
First electrically conductive layer: copper foil, average thickness 12 μm
First resin layer: fluororesin, average thickness 100 μm
Adhesive layer: epoxy resin, average thickness 25 μm
Ground layer: copper foil, average thickness 12 μm
Second electrically conductive layer: copper foil, average thickness 12 μm
Second resin layer: fluororesin, average thickness 100 μm

### Comparative Example 1

A high-frequency substrate 100 of a comparative example 1 shown in FIG. 12 was produced in the same manner as in the example 1 except that the second opening portion and the third opening portion were not provided.

### Evaluation

The high-frequency substrates of the example 1 and the comparative example 1 (each having 250,000 via holes) were evaluated for connection reliability by a thermal shock test. The thermal shock test was performed by repeatedly exposing the high-frequency substrate to a low-temperature environment and a high-temperature environment at a constant cycle. Specifically, the high-frequency substrate was repeatedly exposed to −60° C. and 125° C. in a cycle of 15 minutes, and the connection resistance was measured to calculate a resistance value change rate. When the resistance value change rate is +5% or more and −5% or less, it is determined that there is an abnormality. In the example 1, the breakage occurred in a part of the sample in 2000 cycles of the thermal shock, and the resistance value change rate was +5% or more. In the comparative example 1, the breakage occurred in all the samples in 1000 cycles, and the resistance value change rate was +5% or more. As described above, the high-frequency substrate of the comparative example 1 had a result that the connection reliability was lower than the connection reliability of the high-frequency substrate of the example 1.

As a result, it was shown that the high-frequency substrate according to the present disclosure can reduce the stress applied to the via hole even when a resin having a large coefficient of linear expansion with respect to a temperature change is used.

The embodiments disclosed herein are to be considered in all respects as illustrative and not restrictive. The scope of the present invention is not limited to the configurations of the above-described embodiments, but is defined by the scope of the claims, and is intended to include all modifications within the meaning and scope equivalent to the scope of the claims

### REFERENCE SIGNS LIST

1 first layered body
2 second layered body
3 adhesive layer
4 first via hole
5l second via hole
10 electrically conductive pattern
11 first electrically conductive layer
12 first resin layer
13 signal line
14 ground layer
20 second electrically conductive layer
21 second resin layer
24, 25 peripheral edge portion of opening of second via hole
30, 34, 35 second opening portion
31, 45 first opening portion
36 third opening portion
40 peripheral edge portion of opening of first via hole
50, 60, 70, 80, 90, 100 high-frequency substrate
150 long side
341 curved surface portion
342 straight line portion

1. A high-frequency substrate comprising:
a first layered body in which a first electrically conductive layer and a first resin layer are stacked;
a second layered body in which a second electrically conductive layer and a second resin layer are stacked, the second layered body being disposed so as to face the first layered body;
an adhesive layer bonding the first resin layer and the second resin layer to each other;
a first via hole formed at an inner periphery and a bottom of one or a plurality of connection holes penetrating the first resin layer in a thickness direction; and
a second via hole formed at an inner periphery and a bottom of one or a plurality of connection holes penetrating the second resin layer and the adhesive layer in the thickness direction,
a wherein the first layered body has an electrically conductive pattern stacked on a surface of the first resin layer facing the second layered body,
a wherein the electrically conductive pattern is embedded in the adhesive layer,
a wherein the electrically conductive pattern has a signal line, and ground layerslines disposed on both sides of the signal line,
a wherein a bottom surface of the first via hole is in contact with the ground layer, and the first via hole electrically connects the first electrically conductive layer and the ground layer to each other,
a wherein a bottom surface of the second via hole is in contact with the ground layer, and the second via hole electrically connects the second electrically conductive layer and the ground layer to each other,
wherein the first resin layer and the second resin layer are mainly composed of a resin having a coefficient of linear expansion of 20 ppm/K or more from 20° C. to 120° C.,
wherein the first electrically conductive layer has a first opening portion in a peripheral region of an opening of the first via hole, and
wherein the second electrically conductive layer has a second opening portion in a peripheral region of an opening of the second via hole.

2. The high-frequency substrate according to claim 1,
wherein at least one of the first electrically conductive layer and the second electrically conductive layer further has third opening portions, and
wherein the third opening portions are provided at a position of the first electrically conductive layer indirectly facing the bottom surface of the second via hole and a position of the second electrically conductive layer indirectly facing the bottom surface of the first via hole.
